(19) United States
(12) Patent Application Publication
(10) Pub. No.: US 2026/0206141 A1
(43) Pub. Date: Jul. 16, 2026

(54) SYSTEMS FOR POWER MODULE PACKAGING

(71) Applicant: DANA TM4 ITALIA S.R.L., Vicenza (IT)

(72) Inventors: Pierpaolo ZULPO, Arzignano (IT); Luca VIRZÌ, Vicenza (IT)

(21) Appl. No.: 19/445,333

(22) Filed: Jan. 9, 2026

Related U.S. Application Data
(60) Provisional application No. 63/745,205, filed on Jan. 14, 2025.

(51) Int. Cl. H05K 1/181; H10W 72/00; H10W 74/10

(52) U.S. Cl. CPC H05K 1/181; H10W 72/823; H10W 74/127; H05K 2201/10287; H05K 2201/10977; H05K 2201/2072

(57) ABSTRACT

Systems and methods are provided for a power module. In one example, a system for a power module includes a substrate including a primary body and a perimeter, a plurality of bonds coupled to the perimeter, wherein the plurality of bonds is divided into segments, each segment including multiple loops and linear portions, and a molding compound covering a surface of the substrate and filling openings between loops of the plurality of bonds and the substrate.

### CROSS REFERENCE TO RELATED APPLICATIONS

The present application claims priority to U.S. Provisional Application No. 63/745,205, entitled “SYSTEMS FOR POWER MODULE PACKAGING”, and filed on January 14, 2025. The entire contents of the above-listed application are hereby incorporated by reference for all purposes.

### TECHNICAL FIELD

The present description relates generally to power module packaging and, more specifically, to plastic chip encapsulation of a substrate.

### BACKGROUND AND SUMMARY

Direct-bonded copper (DBC) substrates are used in the power semiconductor industry. An encapsulant may be bonded to the DBC and used to cover dies, power and signal connections, and a perimeter of a thermal exchange surface of a power module. Bonding the encapsulant to the substrate may be time-consuming and challenging due to the fragile materials included with the power module.

Thus, a demand for a method of development of a DBC-based power module with a plastic chip encapsulant is desired. In one example, a system includes a plurality of bonds coupled to a perimeter of a substrate, and a molding compound covering a surface of the substrate and filling openings between loops of the plurality of bonds and the substrate.

It should be understood that the summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE FIGURES

The above, as well as other advantages of the present disclosure, will become readily apparent to those skilled in the art from the following detailed description when considered in light of the accompanying drawings in which:

FIGS. 1A, 1B, and 1C illustrate a bonding phase on the DBC substrate during a power module manufacturing process;

FIG. 2 illustrates a bonding with loops;

FIG. 3A illustrates an encapsulated module;

FIG. 3B illustrates an interior of the encapsulated module;

FIG. 3C illustrates a sectional view of the encapsulated module;

FIG. 4A illustrates a perspective view of the encapsulated module including a heatsink;

FIG. 4B illustrates a sectional view of the encapsulated module including the heatsink;

FIG. 5 illustrates an example thickness of the substrate of the power module; and

FIG. 6 illustrates an example gap between an encapsulation plane and a contact plane between the DBC and the heatsink.

### DETAILED DESCRIPTION

The following description relates to a power module. The disclosure addresses the challenge of plastic chip encapsulation for power modules based on Direct Bonded Copper (DBC) ceramic substrates, which are inherently more fragile than metallic substrates and cannot be easily processed using conventional encapsulation techniques. Traditional packaging solutions often require creating holes or anchoring edges in the substrate material, which can compromise the structural integrity of ceramic-based modules. Additionally, conventional encapsulation processes may negatively impact the thermal exchange capability of the power module due to constraints imposed by the anchoring method, and the highly exothermic curing reaction of epoxy molding compounds can cause thermal degradation if not properly controlled.

The proposed solution introduces a novel anchoring method for the molding compound that utilizes wire or ribbon bonding techniques already employed in the standard production process of electronic power modules. The process may include two steps. First, during the bonding phase, the DBC substrate is configured with an external perimeter area where anchoring bonds are created using either wire bond or ribbon bond techniques, including stitch bonding. Second, during the molding phase, the epoxy plastic molding compound covers the entire surface of the DBC along with its components and electrical connections, flowing into and solidifying within the loops formed by the perimeter bonds, thereby creating a secure anchor through the pull and shear strength of the bonding itself.

This innovative approach provides several significant technical benefits. The method reduces mechanical stress applied to the ceramic substrate, making it particularly suitable for fragile DBC-based power modules. It optimizes the layout and geometry of the DBC by eliminating the demand for anchoring points such as holes, while providing high anchorage strength inherent in the bond welding resistance. The solution ensures optimal thermal contact between the external copper layer of the DBC and the heatsink by anchoring the molding compound internally through the bonds, eliminating the demand for retention via external geometry and preventing the plastic encapsulation from interfering with the dissipative pad contact. Furthermore, the bonds themselves serve as thermal dissipation pathways, reducing the temperature of the power module both during the molding phase and during operational use, with ribbon bonds providing even greater thermal dissipation due to their larger surface area. The disclosure also enables strategic placement of anchoring bonds at thermally critical points beyond just perimeter areas, further enhancing thermal management of hot spots within the power module.

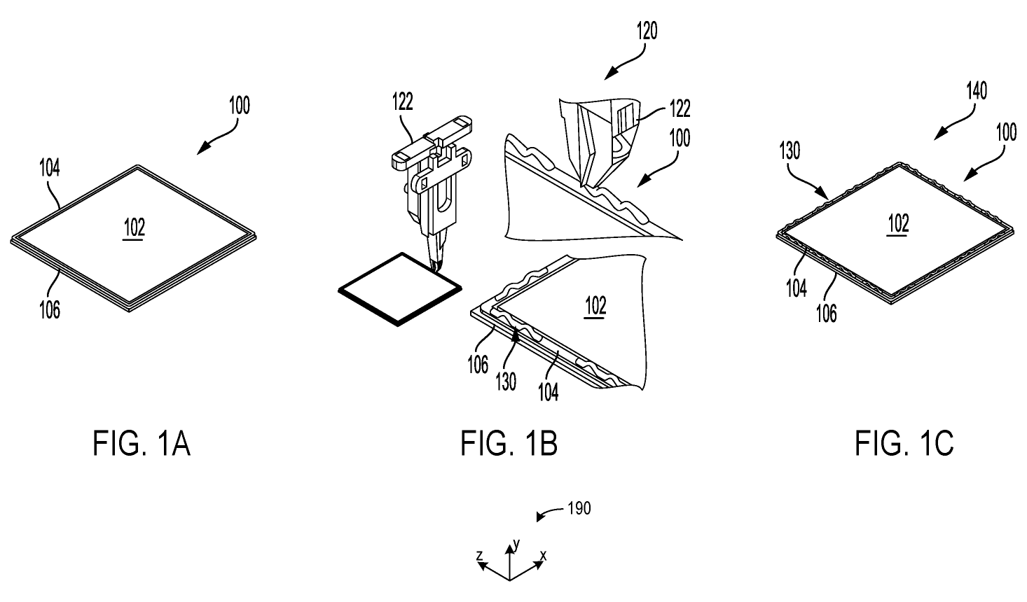

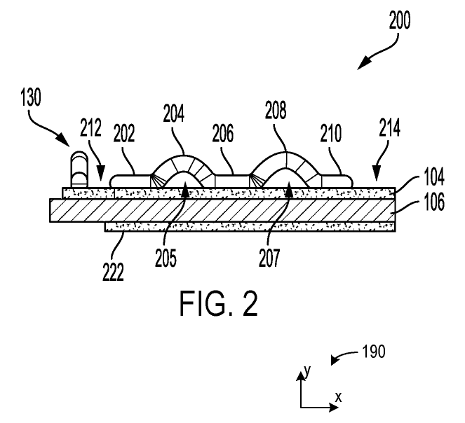

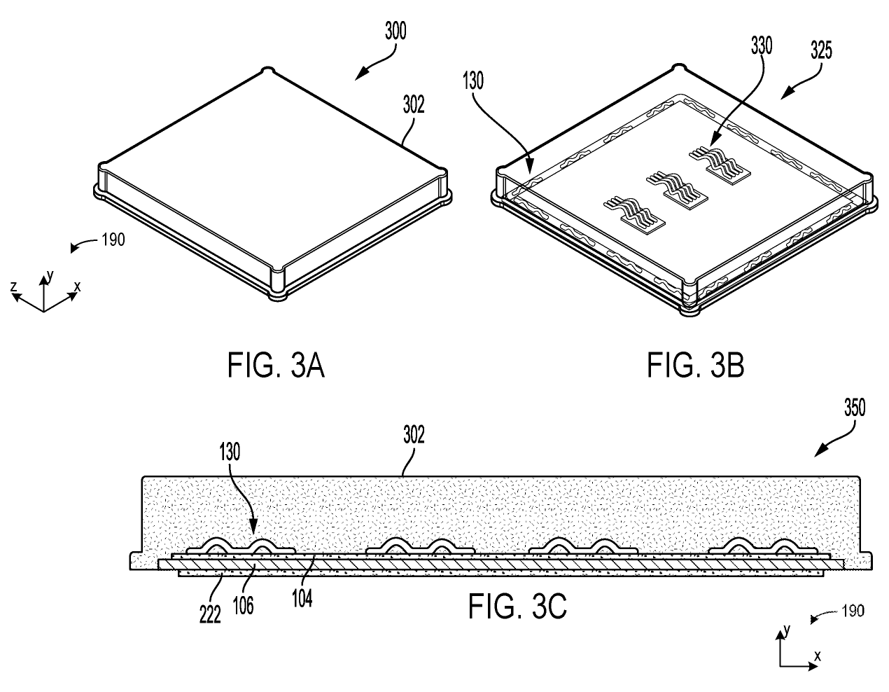

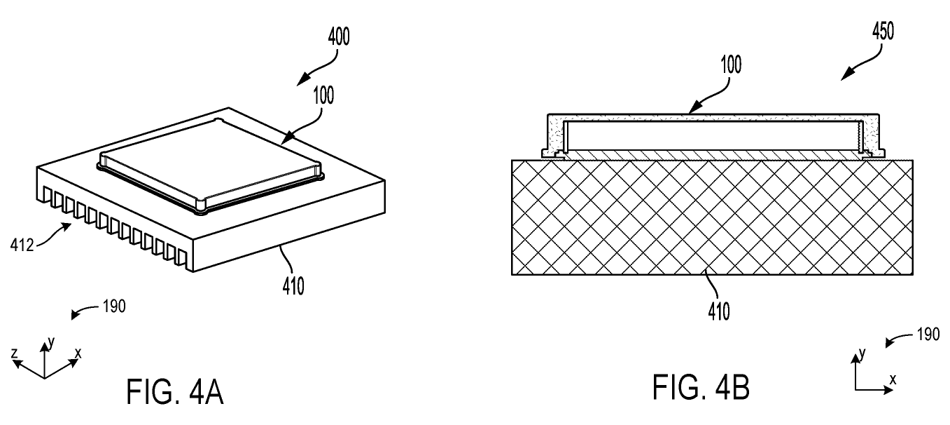

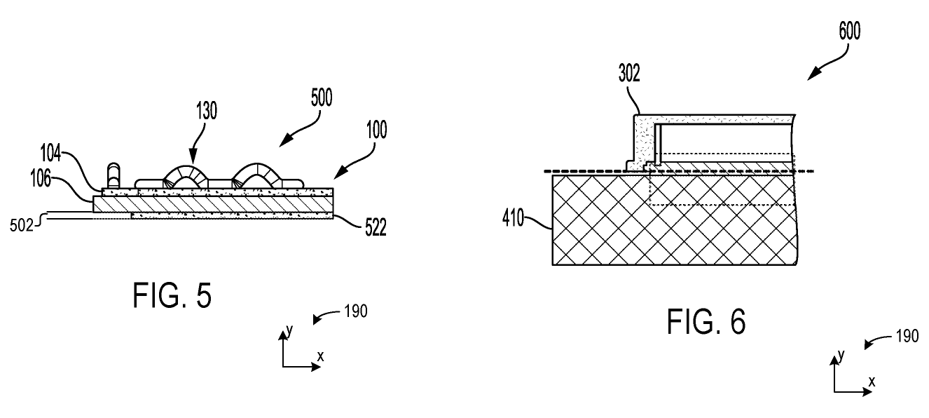

FIGS. 1A, 1B, and 1C illustrate a bonding phase on the DBC substrate during a power module manufacturing process. FIG. 2 illustrates a bonding with loops. FIG. 3A illustrates an encapsulated module. FIG. 3B illustrates an interior of the encapsulated module. FIG. 3C illustrates a sectional view of the encapsulated module. FIG. 4A illustrates a perspective view of the encapsulated module including a heatsink. FIG. 4B illustrates a sectional view of the encapsulated module including the heatsink. FIG. 5 illustrates an example thickness of the substrate of the power module. FIG. 6 illustrates an example gap between an encapsulation plane and a contact plane between the DBC and the heatsink.

In one example, the power module of the present disclosure may include a plastic chip encapsulation of direct-bond copper (DBC) using bonds. A plastic case (e.g., an encapsulant) is clamped to a power module based on a DBC substrate using bonds. The bonds may be ribbon or wire bonds as will be described below. A mechanical strength and a thermal exchange of the power module may be enhanced via the processes described herein.

The DBC substrate may be manufactured according to design demands of the dies and surface mount device (SMD) components. The die and SMD components may be wire, ribbon, or stitch bonded to the DBC. A perimeter may be added to the DBC to provide a surface to which more wire, ribbon, or stitch bonding may be applied to couple the encapsulant to the DBC. In this way, new tools are not demanded during a bonding phase of the encapsulant.

During a molding phase, a molding compound may cover an entire surface of the DBC including the components thereof (e.g., the dies and the SMDs). The molding compound may flow until it solidifies. The molding compound may flow into spaces shaped by the bonds applied to the perimeter of the DBC. As such, a plurality of anchors may be formed. The co-molding between the molding compound and the bonding wires may include an increased strength due to the pull and shear strength of the bonding.

The wire or ribbon bonding technique used to bond the encapsulant may be a technique already used in the production process of the power module. As such, new machinery and/or manufacturing techniques are not utilized when using the methods and systems described herein.

The power module case may be configured to provide thermal dissipation. The thermal dissipation of the molding compound may be relatively low. Previous examples may include adding fillers and/or other additives to boost its thermal conductivity. In the present disclosure, additives and fillers may be avoided via the bonding materials. The bonds may reduce a temperature of the module during each of the molding phase and during an operation phase. As such, the bonds may be applied in thermal hot spots of the perimeter and in areas other than the perimeter. In this way, the disclosure provides support for a power module including a manufacturing process with a reduced number of tools and materials, thereby decreasing a cost and increasing an efficiency to manufacture the power module.

FIGS. 1A-6 show example configurations with relative positioning of the various components. If shown directly contacting each other, or directly coupled, then such elements may be referred to as directly contacting or directly coupled, respectively, at least in one example. Similarly, elements shown contiguous or adjacent to one another may be contiguous or adjacent to each other, respectively, at least in one example. As an example, components laying in face-sharing contact with each other may be referred to as in face-sharing contact. As another example, elements positioned apart from each other with only a space there-between and no other components may be referred to as such, in at least one example. As yet another example, elements shown above/below one another, at opposite sides to one another, or to the left/right of one another may be referred to as such, relative to one another. Further, as shown in the figures, a topmost element or point of element may be referred to as a “top” of the component and a bottommost element or point of the element may be referred to as a “bottom” of the component, in at least one example. As used herein, top/bottom, upper/lower, above/below, may be relative to a vertical axis of the figures and used to describe positioning of elements of the figures relative to one another. As such, elements shown above other elements are positioned vertically above the other elements, in one example. As yet another example, shapes of the elements depicted within the figures may be referred to as having those shapes (e.g., such as being circular, straight, planar, curved, rounded, chamfered, angled, or the like). Further, elements shown intersecting one another may be referred to as intersecting elements or intersecting one another, in at least one example. Further still, an element shown within another element or shown outside of another element may be referred as such, in one example. It will be appreciated that one or more components referred to as being “substantially similar and/or identical” differ from one another according to manufacturing tolerances (e.g., within 1-5% deviation). FIGS. 1A-6 are shown approximately to scale.

Turning now to FIG. 1A, it shows a bonding phase of a DBC substrate 100. The DBC substrate 100 may include a primary body 102 and a perimeter 104. The primary body 102 and the perimeter 104 may be separate pieces with a gap (e.g., a trough) 108 arranged therebetween. In one example, the primary body 102 and the perimeter 104 may be isolated parts on a top copper layer of the DBC substrate 100. The DBC substrate 100 may be coupled to a base 106. The gap 108 may correspond to a region of the base 106 exposed between the perimeter 104 and the primary body 102.

An axis system 190 is shown including three axes, an x-axis parallel to a horizontal direction, a y-axis parallel to a vertical direction, and a z-axis normal to each of the x- and y-axes. The primary body 102 and the perimeter 104 may include an identical height measured along the y-axis.

Turning now to FIG. 1B, it shows an application 120 of a plurality of bonds 130. An applicator 122 may eject the plurality of bonds 130 along the perimeter 104 of the DBC substrate 100. In one example, the plurality of bonds 130 may be applied in segments. Each of the segments may include loops and linear portions, described in greater detail with respect to FIG. 2. The plurality of bonds 130 may include a plurality of loops and linear segments, wherein the plurality of loops extend along the y-axis away from the perimeter 104.

Turning now to FIG. 1C, it shows a final product 140 of the bonding phase including the plurality of bonds 130 bonded to the perimeter 104. More specifically, the plurality of bonds 130 are bonded to a side of the perimeter 104 facing away from the base 106. In some examples, additionally or alternatively, the plurality of bonds 130 may be applied to the primary body 102. Locations at which the plurality of bonds 130 may be applied to the primary body 102 may correspond to areas of susceptible to increased temperatures.

Turning now to FIG. 2, it shows an embodiment of a segment 200 of the plurality of bonds 130. The segment 200 may include a first linear portion 202. The first linear portion 202 may be in face-sharing contact with and parallel to the perimeter 104 along its entire length. In one example, each segment 200 may include at least one loop or semi-circle arranged between two linear segments. Each of the plurality of bonds may be spaced away from neighboring bonds of the plurality of bonds 120. In other examples, the plurality of bonds may be contiguous such that the bonds touch neighboring bonds.

The segment 200 may further include a first semi-circle 204. The first semi-circle 204 may be lifted, along the y-axis, relative to the perimeter 104 such that a first opening 205 is positioned between the first semi-circle 204 and the perimeter 104. In one example, the first semi-circle 204 is a first loop.

A second linear portion 206 may be connected to the first semi-circle 204. In this way, the first semi-circle 204 may be sandwiched between the first linear portion 202 and the second linear portion 206. The second linear portion 206 may be in face-sharing contact with and parallel to the perimeter 104 along its entire length. In one example, a length of the second linear portion 206 may be identical to or different than a length of the first linear portion 202.

The segment 200 may further include a second semi-circle 208. The second semi-circle 208 may be connected to the second linear portion 206. In this way, the second linear portion 206 may be sandwiched between the first semi-circle 204 and the second semi-circle 208. The second semi-circle 208 may be lifted relative to the perimeter 104 such that a second opening 207 is positioned between the second semi-circle 208 and the perimeter 104. In one example, a size of the second opening 207 may be substantially identical to a size of the first opening 205. In one example, the second semi-circle 208 is a second loop.

A third linear portion 210 may be connected to the second semi-circle 208. In this way, the second semi-circle 208 may be sandwiched between the second linear portion 206 and the third linear portion 210. The third linear portion 210 may be in face-sharing contact with and parallel to the perimeter 104 along its entire length. In one example, a length of the third linear portion 210 may be identical to or different than the lengths of the first linear portion 202 and the second linear portion 206.

In one example, an entirety of the segment 200 may be a single piece. For example, a single bond wire or bond ribbon may shape each of the first linear portion 202, the first semi-circle 204, the second linear portion 206, the second semi-circle 208, and the third linear portion 210.

Spaces may be arranged between neighboring segments of the plurality of bonds 130. For example, a first space 212 may be arranged between the first linear portion 202 and a neighboring segment of the plurality of bonds 130. A second space 214 may be arranged between the third linear portion 210 and a neighboring segment of the plurality of bonds 130.

The segment 200 may include a uniform diameter through its length, including through each of the linear segments and loops. Additionally, or alternatively, due to the application of the bonds, sections of the linear portions may include a diameter less than a diameter of the loops. Additionally, or alternatively, at the areas of reduced diameter, the linear segments may include a flat surface.

Turning now to FIG. 3A, it shows an example of the encapsulated power module 300. An encapsulant 302 may cover the power module. The encapsulant 302 may be an epoxy plastic. In one example, the encapsulant 302 does not contact a side of the base 106 to which the perimeter 104 and the primary body are not coupled. The side of the base 106 free of the encapsulant 302 may be exposed, or coupled to an additional element 222. The additional element 222 may be substrate, a dissipative plate, or other feature. FIG. 3B shows a transparent view 325 of the encapsulated power module. The transparent view 325 shows a plurality of bonds 330 coupled to a device of the power module on the primary body, such as a SMD of the power module. FIG. 3C shows a sectional view 350 of the encapsulated power module 300. Therein, the encapsulant 302 completely surrounds each of the plurality of bonds 130. In one example, a molding compound, which hardens to form the encapsulant 302, may flow into the openings corresponding to the semi-circles of the segments of the plurality of bonds. The molding compound may flow across an entirety of the surface of the DBC, along with the components arranged thereon, and through the openings shaped by the semi-circles of the plurality of bonds. The molding compound may harden, thereby creating an anchor for the encapsulant. In this way, the encapsulant 302 may be a single solid piece, as shown in FIG. 3C, that bonds to surfaces of the power module and to surfaces of the plurality of bonds 130 and plurality of bonds 330.

A curing of the molding compound may include an exothermic reaction. The curing may include maintain the exothermic reaction within a desired temperature range to avoid a temperature increase of the power module above a threshold temperature. The plurality of bonds may increase thermal dissipation such that thermal degradation during the curing of the molding compound and during operation of the power module may be avoided.

The dimensions of the encapsulant 302 may be greater than the base 106 and the perimeter 104 along each of the x-, y-, and z-axes. As shown in FIG. 3C, a portion 352 of the encapsulant 302 overhangs and extends beyond the profiles of the perimeter 104 and the substrate 106.

Turning now to FIGS. 4A and 4B, they show embodiments 400 and 450 of a dissipative plate 410 coupled to the DBC 100. The dissipative plate 410 may be coupled to a side of the DBC 100 opposite the plurality of bonds 130 and other components. The dissipative plate 410 may be interchangeably referred to herein as a heat sink 410.

The dissipative plate 410 may include a plurality of fins 412. The plurality of fins 412 may be arranged on a first side of the dissipative plate 410. The DBC 100 may be coupled to a second side of the dissipative plate 410, wherein the second side is opposite the first side. The plurality of fins 412 may increase a cooling capacity of the dissipative plate 410.

Turning now to FIG. 5, it shows an embodiment 500 of the DBC 100 including the perimeter 104, the base 106, and a dissipative plate 522. In one example, the dissipative plate 522 is copper and configured as a bottom layer of the DBC 100. The dissipative plate 522 may force thermal transfer between an external layer of the DBC 100 and the heat sink 410. A thickness 502, measured along the y-axis, of the dissipative plate 522 may be between 0.1 and 1.0 mm. In one example, the thickness 502 is equal to exactly 0.3 mm.

FIG. 6 shows an embodiment 600 of the DBC 100 in thermal contact with the heat sink 410. The DBC 100 may be thermal contact with the heat sink 410 via the internal anchoring provided by the molding compound and the plurality of bonds. As such, an external anchoring and/or coupling is not demanded for the encapsulant and thermal properties of the power module may be enhanced relative to other examples. In one example, the encapsulant 302 may be spaced away by a distance equal to the thickness 502 of the dissipative plate 522. The distance may be less than 1 mm. In some examples, additionally or alternatively, the distance may be less than 0.5 mm. In one example, the distance is 0.3 mm. The DBC 100, including the encapsulant 302 and all other components of the DBC 100 are spaced away from the heat sink 410 via the dissipative plate 222.

In this way, a plastic chip encapsulation process applied to a power module based on a DBC substrate may include increased robustness and thermal performance. By using the bonds to anchor the molding compound to the substrate, a reduced stress may be applied to the substrate which may be more suitable for power modules arranged on a ceramic and/or non-metallic base that is more fragile. A layout of the DBC may be optimized as anchoring points may be avoided, thereby decreasing manufacturing time and costs. The anchor strength provided by the bonds is relatively high, the bonds further allow a dissipative plate of the DBC to directly contact a heat sink due to the exclusion of the external coupling points. By doing this, a temperature of the power module is reduced during the manufacturing process and during operation.

The disclosure also provides support for a system including a plurality of bonds coupled to a perimeter of a substrate, and a molding compound covering a surface of the substrate and filling openings between loops of the plurality of bonds and the substrate. In a first example of the system, the molding compound covers the plurality of bonds. In a second example of the system, optionally including the first example, the substrate is a ceramic substrate. In a third example of the system, optionally including one or both of the first and second examples, the substrate is non-metallic. In a fourth example of the system, optionally including one or more or each of the first through third examples, the substrate is direct-bond copper (DBC). In a fifth example of the system, optionally including one or more or each of the first through fourth examples, the perimeter extends around a primary body of the substrate, and wherein bonds of the plurality of bonds are coupled to the primary body. In a sixth example of the system, optionally including one or more or each of the first through fifth examples, the plurality of bonds is arranged in segments, each segment comprising multiple loops and linear portions, wherein the loops and the linear portions alternate along each segment.

The disclosure also provides support for a system for a power module including a substrate comprising a primary body and a perimeter, a plurality of bonds coupled to the perimeter, wherein the plurality of bonds is divided into segments, each segment comprising a plurality of loops and a plurality of linear portions, and a molding compound covering a surface of the substrate and filling openings between loops of the plurality of bonds and the substrate. In a first example of the system, each segment comprises at least two loops sandwiched alternating with linear portions. In a second example of the system, optionally including the first example, each loop is raised relative to the surface of the substrate. In a third example of the system, optionally including one or both of the first and second examples, each segment is spaced away from a neighboring segment. In a fourth example of the system, optionally including one or more or each of the first through third examples, the plurality of bonds is a wire bond or a ribbon bond, and wherein each segment is a continuous piece of the wire bond or the ribbon bond. In a fifth example of the system, optionally including one or more or each of the first through fourth examples, the molding compound is epoxy. In a sixth example of the system, optionally including one or more or each of the first through fifth examples, the substrate is coupled to a first side of a base and a dissipative plate is coupled to a second side of the base. In a seventh example of the system, optionally including one or more or each of the first through sixth examples, the dissipative plate is in face-sharing contact with a heat sink.

The disclosure also provides support for a system including a base coupled to a substrate, and a plurality of bonds coupled to a surface of the substrate opposite the base, wherein each of the plurality of bonds comprises at least one semi-circle positioned between two linear portions. In a first example of the system, an opening is arranged between the at least one semi-circle and the surface of the substrate. In a second example of the system, optionally including the first example, an encapsulant covers the base, the substrate, and the plurality of bonds, and wherein the encapsulant fills the opening between the at least one semi-circle and the surface of the substrate. In a third example of the system, optionally including one or both of the first and second examples, a dissipative plate is coupled to a surface of the base. In a fourth example of the system, optionally including one or more or each of the first through third examples, each of the plurality of bonds is spaced away from neighboring bonds of the plurality of bonds. As used herein, the term “approximately” is construed to mean plus or minus five percent of the range unless otherwise specified.

The following claims particularly point out certain combinations and sub-combinations regarded as novel and non-obvious. These claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure.

1. A system, comprising:
a plurality of bonds coupled to a perimeter of a substrate; and
a molding compound covering a surface of the substrate and filling openings between loops of the plurality of bonds and the substrate.

2. The system of claim 1, wherein the molding compound covers the plurality of bonds.

3. The system of claim 1, wherein the substrate is a ceramic substrate.

4. The system of claim 1, wherein the substrate is non-metallic.

5. The system of claim 1, wherein the substrate is direct-bond copper (DBC).

6. The system of claim 1, wherein the perimeter extends around a primary body of the substrate, and wherein bonds of the plurality of bonds are coupled to the primary body.

7. The system of claim 1, wherein the plurality of bonds is arranged in segments, each segment comprising multiple loops and linear portions, wherein the loops and the linear portions alternate along each segment.

8. A system for a power module, comprising:
a substrate comprising a primary body and a perimeter;
a plurality of bonds coupled to the perimeter, wherein the plurality of bonds is divided into segments, each segment comprising a plurality of loops and a plurality of linear portions; and
a molding compound covering a surface of the substrate and filling openings between loops of the plurality of bonds and the substrate.

9. The system of claim 8, wherein each segment comprises at least two loops sandwiched alternating with linear portions.

10. The system of claim 8, wherein each loop is raised relative to the surface of the substrate.

11. The system of claim 8, wherein each segment is spaced away from a neighboring segment.

12. The system of claim 8, wherein the plurality of bonds is a wire bond or a ribbon bond, and wherein each segment is a continuous piece of the wire bond or the ribbon bond.

13. The system of claim 8, wherein the molding compound is epoxy.

14. The system of claim 8, wherein the substrate is coupled to a first side of a base and a dissipative plate is coupled to a second side of the base.

15. The system of claim 14, wherein the dissipative plate is in face-sharing contact with a heat sink.

16. A system, comprising:
a base coupled to a substrate; and
a plurality of bonds coupled to a surface of the substrate opposite the base, wherein each of the plurality of bonds comprises at least one semi-circle positioned between two linear portions.

17. The system of claim 16, wherein an opening is arranged between the at least one semi-circle and the surface of the substrate.

18. The system of claim 17, wherein an encapsulant covers the base, the substrate, and the plurality of bonds, and wherein the encapsulant fills the opening between the at least one semi-circle and the surface of the substrate.

19. The system of claim 16, wherein a dissipative plate is coupled to a surface of the base.

20. The system of claim 16, wherein each of the plurality of bonds is spaced away from neighboring bonds of the plurality of bonds.
